(19) United States
(12) Patent Application Publication
(10) Pub. No.: US 2011/0297229 A1
(43) Pub. Date: Dec. 8, 2011

(54) INTEGRATED CONCENTRATING PHOTOVOLTAICS

(75) Inventors: Tian Gu, Newark, DE (US); Michael W. Haney, Oak Hill, VA (US)

(73) Assignee: University of Delaware, Newark, DE (US)

(21) Appl. No.: 13/151,614

(22) Filed: Jun. 2, 2011

Related U.S. Application Data
(60) Provisional application No. 61/350,591, filed on Jun. 2, 2010.

(51) Int. Cl. H01L 31/18; G02B 6/32; G02B 6/10; G02B 6/26

(52) U.S. Cl. 136/259; 385/31; 385/33; 264/1.24

(57) ABSTRACT

Optical sheets, light collection and conversion systems and methods of forming optical sheets are provided. An optical sheet includes a light guide layer having at least one light guide and a light concentrator layer adjacent to the light guide layer for concentrating incident light. Each light guide has a substantially uniform thickness with respect to a propagation direction of light through the light guide and includes a plurality of input-coupling elements and at least one output-coupling element. The light concentrator layer includes a plurality of concentrator elements optically coupled to the plurality of input-coupling elements of the respective light guide. Each light guide is configured to combine the concentrated light from the respective plurality of concentrator elements and to guide the combined light to the at least one output-coupling element.

### CROSS REFERENCE TO RELATED APPLICATIONS

This application is related to and claims the benefit of U.S. Provisional Application No. 61/350,591 entitled “INTEGRATED CONCENTRATING PHOTOVOLTAICS” filed on Jun. 2, 2010, the contents of which are incorporated herein by reference.

### FIELD OF THE INVENTION

The present invention relates to optics and power conversion systems. More particularly, the present invention relates to methods of light collection, light collection devices and light collection and conversion systems having a light concentrator layer and a light guide layer including at least one light guide.

### BACKGROUND OF THE INVENTION

Photovoltaic (PV) devices (i.e., solar cells), are devices capable of converting solar radiation into electrical energy. PV concentrator structures are known to be used with solar cells for the collection and concentration of sunlight. Conventional PV concentrator structures may increase the energy conversion efficiency of PV systems. Improvements in PV concentrator structures are needed to achieve high-efficiency, low-cost and compact light collection systems.

### SUMMARY OF THE INVENTION

The present invention is embodied in an optical sheet. The optical sheet includes a light guide layer having at least one light guide and a light concentrator layer adjacent to the light guide layer for concentrating incident light. Each light guide includes a plurality of input-coupling elements and at least one output-coupling element. Each light guide has a substantially uniform thickness with respect to a propagation direction of light through the light guide. The light concentrator layer includes a plurality of concentrator elements optically coupled to the plurality of input-coupling elements of the respective light guide. Each light guide is configured to combine the concentrated light from the respective plurality of concentrator elements and to guide the combined light to the at least one output-coupling element.

The present invention is also embodied in a light collection and conversion system. The light collection and conversion system includes at least one optical sheet and a light conversion apparatus. Each optical sheet includes a light guide layer having at least one light guide and a light concentrator layer adjacent to the light guide layer for concentrating incident light. Each light guide has a substantially uniform thickness with respect to a propagation direction of light through the light guide. A plural number of concentrator elements of the light concentrator layer are optically coupled to each light guide. The light conversion apparatus is optically coupled to the at least one optical sheet via the at least one light guide.

The present invention is also embodied in a method of forming an optical sheet. The method includes forming a light guide layer, forming at least one light guide in the light guide layer having a substantially uniform thickness with respect to a propagation direction of light through the light guide, forming a plurality of input-coupling elements and at least one output-coupling element for each light guide, forming a light concentrator layer including a plurality of concentrator elements configured to be optically aligned with the plurality of input-coupling elements of the respective light guide and disposing the light guide layer on the light concentrator layer.

### BRIEF DESCRIPTION OF THE DRAWINGS

The invention may be understood from the following detailed description when read in connection with the accompanying drawing. It is emphasized, according to common practice, that various features of the drawings may not be drawn to scale. On the contrary, the dimensions of the various features may be arbitrarily expanded or reduced for clarity. Moreover, in the drawing, common numerical references are used to represent like features. Included in the drawing are the following figures:

FIG. 1 is a functional block diagram of an exemplary light collection and conversion system, according to an embodiment of the present invention;

FIG. 2 is a cross-sectional diagram of an exemplary optical sheet coupled to a photovoltaic (PV) cell, according to an embodiment of the present invention;

FIGS. 3A and 3B are cross-sectional diagrams of a concentrator element and a light guide of the optical sheet shown in FIG. 2, according to embodiments of the present invention;

FIG. 3C is an overhead view diagram of a concentrator element and a light guide of the optical sheet shown in FIG. 2, according to another embodiment of the present invention;

FIGS. 4A and 4B are overhead view diagrams of exemplary light collection and conversion systems, according to embodiments of the present invention;

FIG. 5A is a cross-sectional diagram of an exemplary light collection and conversion system, according to another embodiment of the present invention;

FIG. 5B is a cross-sectional diagram of a portion of the optical sheet shown in FIG. 5A;

FIG. 6A is a cross-sectional diagram of a light collection and conversion system, according to another embodiment of the present invention;

FIG. 6B is a cross-sectional diagram of a portion of the light guide shown in FIG. 6A;

FIGS. 7A and 7B are cross-sectional diagrams of exemplary light collection and conversion systems, according to another embodiment of the present invention;

FIGS. 8A and 8B are cross-sectional diagrams of exemplary light collection and conversion systems, according to further embodiments of the present invention;

FIG. 9 is an exploded perspective view diagram of an exemplary light collection and conversion system, according to another embodiment of the present invention;

FIG. 10 is an exploded perspective view diagram of a portable device including an exemplary light collection and conversion system, according to an embodiment of the present invention; and

FIG. 11 is a perspective view diagram of an exemplary roof-mounted light collection and conversion system, according to an embodiment of the present invention.

### DETAILED DESCRIPTION OF THE INVENTION

Aspects of the present invention relate optical sheets for collecting light, light collection and conversion systems and methods of forming an optical sheet. An exemplary optical sheet may include a light guide layer and a light concentrator layer adjacent to the light guide. The light concentrator layer may include a plurality of concentrator elements optically coupled to light guide of the light guide layer, for collecting and concentrating light. An exemplary light guide may combine concentrated light from plural concentrator elements and may direct the combined light to at least one output aperture. Light output from the light guide of the light guide layer may be directly or remotely coupled to a PV cell. According to an exemplary embodiment, an optical sheet may include a plurality of light guides, where each light guide may be coupled (either remotely or directly) to a respective PV cell.

Conventional PV concentrator structures, such as refractive or reflective optical elements (for example, mirrors or lenses) have been applied to large-scale PV applications. For example, discrete refractive or reflective optical elements have been used to condense incident sunlight onto individual PV cells of a PV cell array positioned at a focal plane of the optical elements. PV cells of the array may be connected together and used to convert sunlight to electricity.

Conventional PV concentrators, however, typically suffer from a lack of compactness, may be structurally complex and may be expensive to manufacture and integrate with smaller-scale PV applications (such as for portable devices). The heat management, weight and space limitations of smaller-scale PV applications may also be of concern. In addition, as the aspect ratio (width/height) of future solar panels continues to increase (for example, in order to achieve a small form factor), the resulting decrease in the dimensions of the PV sub-modules may push PV cells to their physical limits. This may result in problems with performance, fabrication, cost, tolerance to misalignment, etc. Thus, conventional PV concentrators are typically not directly portable to applications for small-scale mobile electronics (for example, cellular phones or portable computers).

According to aspects of the present invention, the collection of light is provided by an optical sheet that may be spatially decoupled from a light conversion device (such as one or more solar cells), via the use of a light guide layer including one or more light guides. In an exemplary optical sheet, a single light guide is optically coupled to multiple concentrator elements (i.e., a sub-array of concentrator elements). Accordingly, an exemplary light collection and conversion system allows for a single PV cell to receive sunlight collected from multiple concentrator elements via the light guide. Thus, an exemplary light collection and conversion system of the present invention may still be functional, even if some of the concentrator elements are obstructed. Because an exemplary light collection and conversion system includes light guides, PV cells do not need to be placed beneath a respective concentrator element and a light conversion apparatus may be remotely coupled to the optical sheet. Therefore, optical power collection and conversion may be managed independently in the light collection and conversion systems of the present invention. Because an exemplary optical sheet and light conversion apparatus may be decoupled from each other, the optical sheet and light conversion apparatus may be fabricated independently and the integration of the optical sheet and light conversion apparatus may be improved. As a result, exemplary light collection and conversion systems of the present invention may improve the system compactness, the structural flexibility, a mass production capability and may reduce the cost of production.

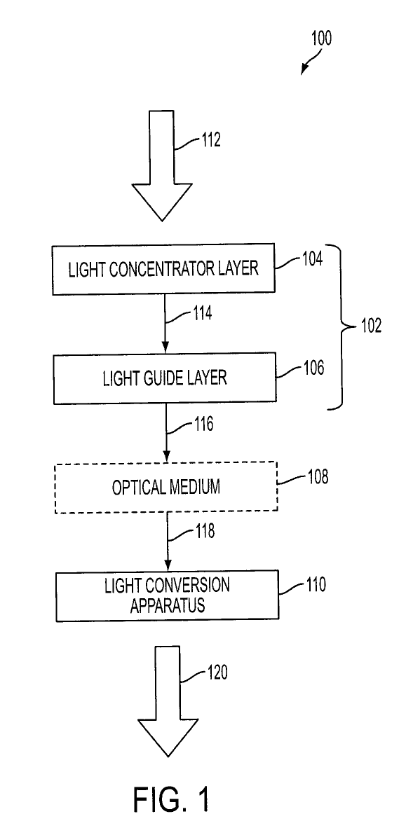

Referring to FIG. 1, a functional block diagram of exemplary light collection and conversion system 100 is shown. System 100 includes optical sheet 102 and light conversion apparatus 110. According to one embodiment, optical sheet 102 may be directly optically coupled to light conversion apparatus 110. According to another embodiment, optical sheet 102 may be remotely optically coupled to light conversion apparatus 110 via optical medium 108. Optical medium 108 may include, for example, a light guide layer or one or more optical fibers. Light conversion apparatus 110 may include one or more PV cells, as well as other electronics (such as opto-electrical components) and/or secondary optical components.

System 100 represents an optical concentrator based PV system in which optics for light collection are provided as one component (i.e., optical sheet 102) and a light conversion component for converting light to an electrical signal is provided as a separate component (i.e., light conversion apparatus 110), and integrated as one system 100. Accordingly, in system 100, the optical components of optical sheet 102 and PV cells of light conversion apparatus 110 may be integrated and maintained substantially independently.

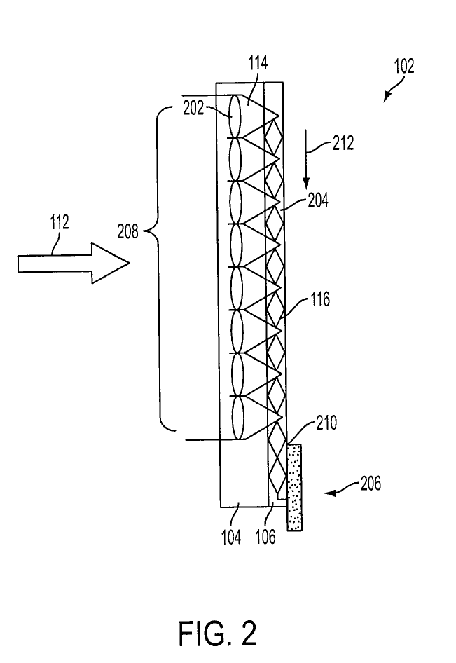

Light concentrator layer 104 is configured to collect input (i.e., incident) light 112 and to generate concentrated light 114. Light guide layer 106 receives concentrated light 114 and is configured to output guided light 116 at a location remote from concentrator elements 202 (FIG. 2) of light concentrator layer 104. Guided light 116 may be directly provided to light conversion apparatus 110 or may be remotely provided to light conversion apparatus 110 via optical medium 108. Optical medium 108 (such as one or more optical fibers) may receive guided light 116 and may transfer guided light 116, as transferred light 118, to light conversion apparatus 110. Light concentrator layer 104 and light guide layer 106 are described further below with respect to FIG. 2.

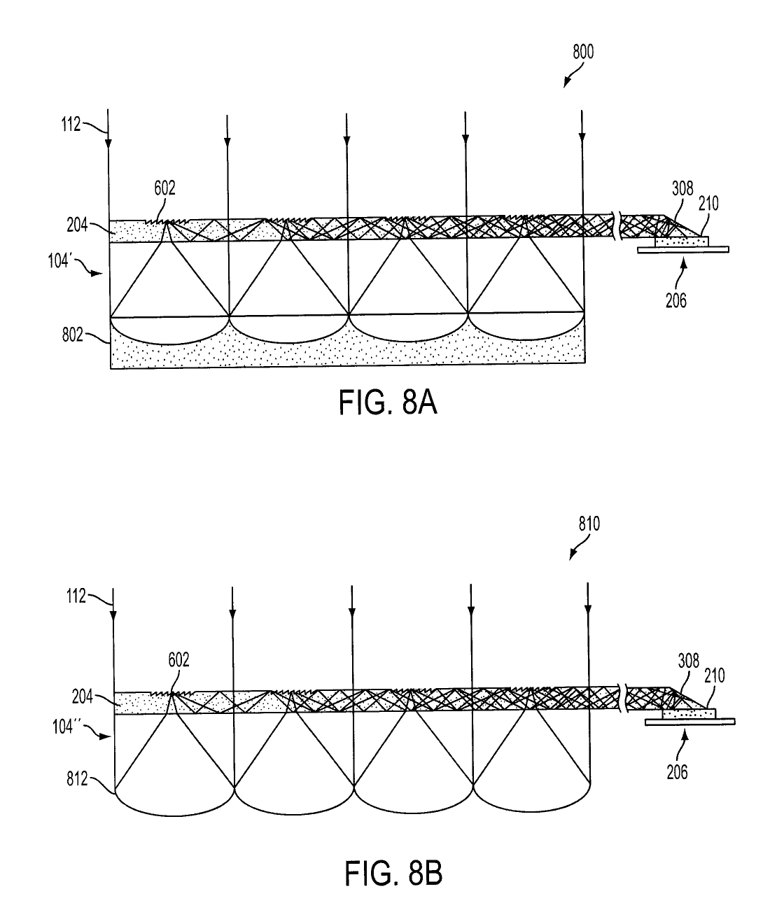

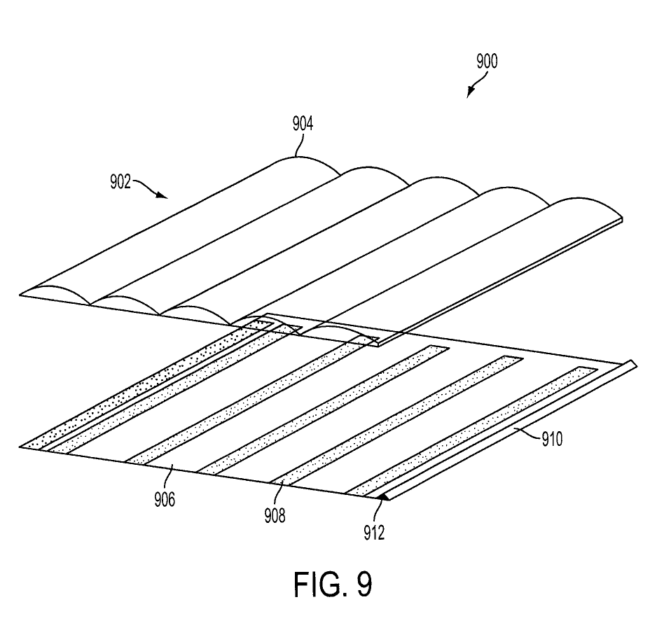

Referring to FIG. 2, a cross-sectional diagram of exemplary optical sheet 102 including light concentrator layer 104 and light guide layer 106 is shown. Optical sheet 102 including light concentrator layer 104 disposed adjacent to light guide layer 106. In FIG. 2, light concentrator layer 104 is shown as directly receiving input light 112 and providing concentrated light 114 to light guide layer 106. According to another embodiment, light guide layer 106 may be configured to receive and pass input light 112 to light concentrator layer 104 (as shown in FIGS. 8A and 8B). Light concentrator layer 104 may then reflect concentrated light 114 to light guide layer 106.

Light concentrator layer 104 may include a plurality of concentrator elements 202, arranged as concentrator array 208, to collect input light 112 and generate concentrated light 114. Concentrator elements 202 may include any suitable refractive-based concentrator (such as an objective lens or a Fresnel lens) and/or reflective-based concentrators (such as parabolic or compound-shaped reflectors).

Light guide layer 106 may include at least one light guide 204. Concentrator elements 202 of concentrator array 208 are optically coupled to light guide 204 and are configured to provide concentrated light 114 to small focal areas along light guide 204. Light guide 204 may combine concentrated light 114 from plural concentrator elements of concentrator array 208 and direct the combined light, as guided (and combined) light 116 to output aperture 210, for conversion to an electrical signal by PV cell 206.

Light guide 204 is configured to confine concentrated light 114 in a two-dimensional plane (as guided light 116), and propagates guided light 116 to output aperture 210. Light guide 204 may be configured to cause total internal reflection of concentrated light 114 from concentrator array 208, which propagates along light guide 204 in accordance with Snell's law (where total internal reflection occurs when the angle of concentrated light 114 incident on a surface of light guide 204 is greater than the critical angle). According to another embodiment, light guide 204 may include one or more reflective coatings on an inner surface of light guide 204 or other suitable mechanisms to transport guided light 116 to output aperture 210.

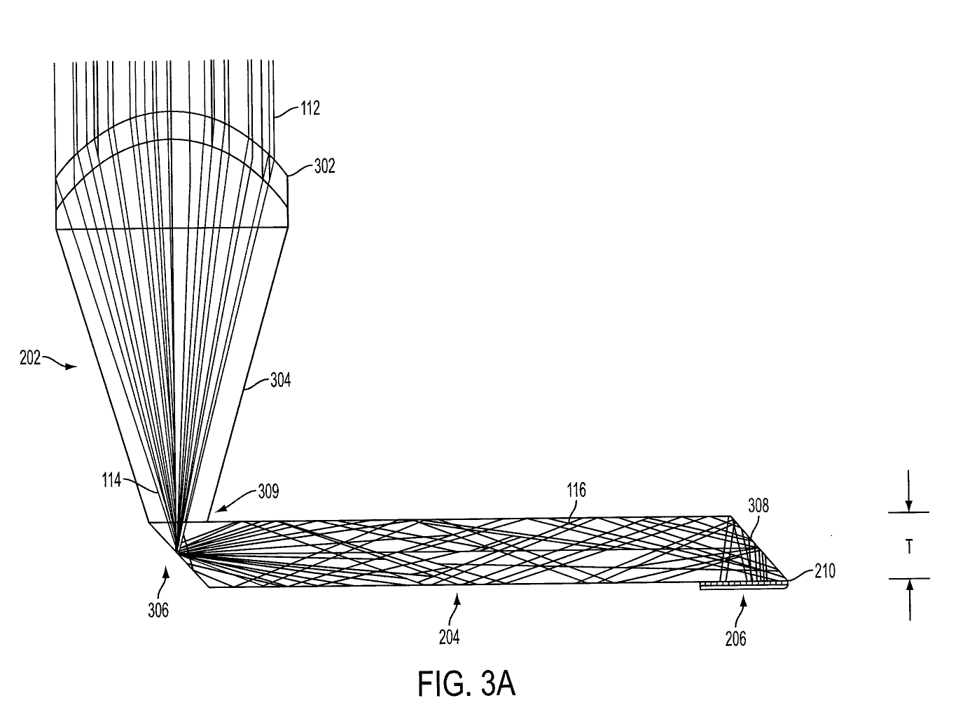

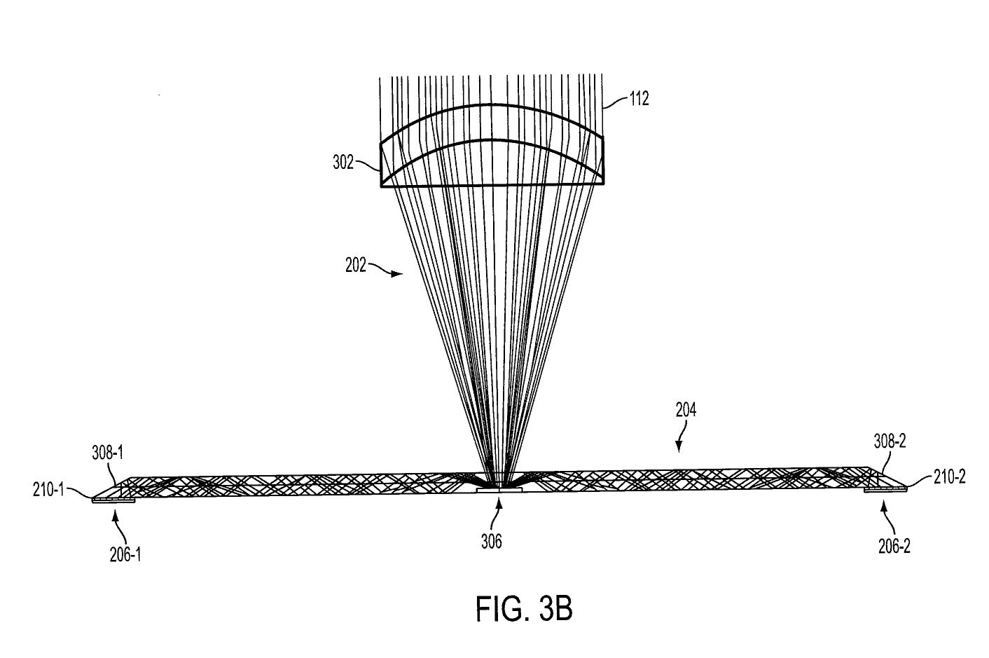

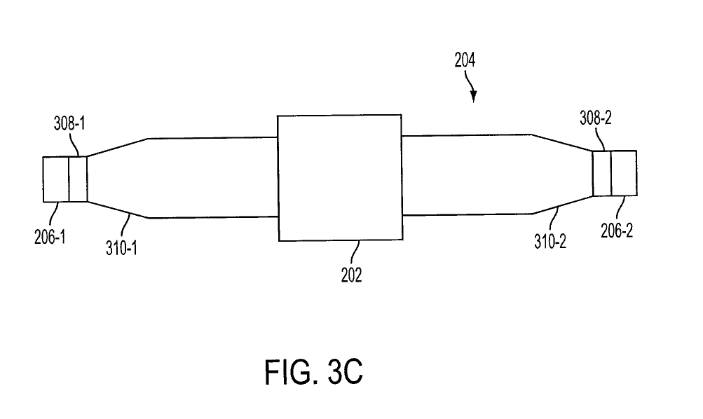

In general, light guide 204 is configured to have a substantially uniform thickness (T shown in FIG. 3A) with respect to a propagation direction of light (illustrated as arrow 212) through light guide 204. The thickness T of light guide 204 may vary depending upon the scale of system 100. For example, if system 100 represents a micro-optical concentrator system, light guide 204 may be between about a sub-wavelength to hundreds of wavelengths in thickness. For larger scale applications, light guide 204 may have a similar thickness range or may be greater than or equal to about several millimeters in thickness. Light guide 204, without being limiting, may include, for example, a planar waveguide, a rectangular waveguide, a structured waveguide (i.e., a tapered waveguide), an optical plate, an optical fiber or any other type of wave path capable of confining and guiding concentrated light 114 to output aperture 210. Because light guide 204 may be fabricated with low-loss crossings, turns, splittings and combining elements, light guide 204 may be capable of transporting guided light 116 to any arbitrary location or locations on light guide layer 106. Light guide 204 may include additional optical components to further shape/concentrate the light or to provide a predetermined irradiation pattern on PV cell 206. Because light guide 204 is configured to have a substantially uniform thickness T (FIG. 3A), it may be simple to form light guide 204 in light guide layer 106, as well as to form multiple light guides 204 in light guide layer 106. Thus, costs for producing light guide layer 106 may be reduced.

Light concentrator layer 104 and light guide layer 106 may each be formed of any suitable material that is transparent to visible light. Examples of materials for light concentrator layer 104 and light guide layer 106 include, without being limited to, optical glass (such as silica glass, fluoride glass, phosphate glass, chalcogenide glass), polymers (such as SU-8, SPR-220, P4620, KMPR-1000) and transparent plastic material (such as poly(methyl methacrylate) (PMMA)). Other example materials include semiconductors that are transparent to the spectrum band of the propagating light (for example, silicon, GaAs and GaP).

In FIG. 2, output aperture 210 of light guide 204 is illustrated as being directly coupled to PV cell 206. According to another embodiment, output aperture 210 may be remotely coupled to PV cell 206, for example, by an optical fiber (for example, with first and second ends connected to output aperture 210 and PV cell 206, respectively). Light from output aperture 210 may also be coupled to an array of PV cells 206 (not shown).

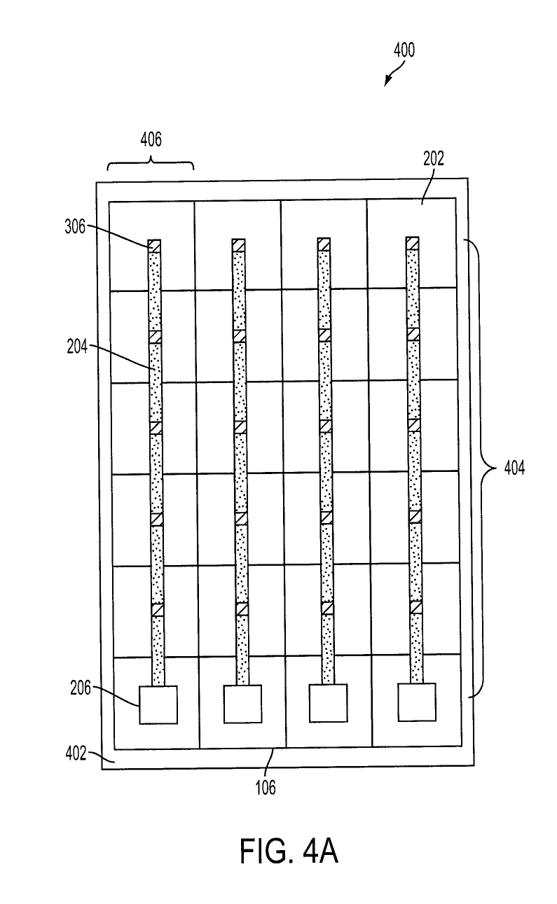

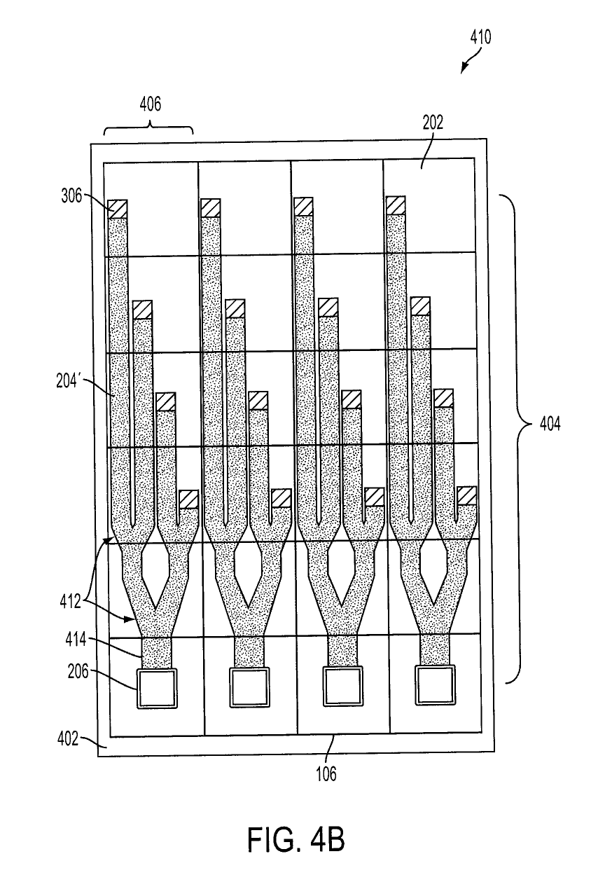

Optical sheet 102 may include one light guide 204 (for example, as shown in FIG. 9) or may include multiple light guides 204 with associated output apertures 210 (for example, as shown in FIG. 4A). Multiple light guides 204 may be disposed in a single plane of light guide layer 106, to produce a more compact optical sheet 102, and for ease of fabrication and integration. Light guide 204 may include a single light guide coupled to concentrator array 208 (for example, as shown in FIG. 4A) or may include multiple light guides 204′ combined together into one light guide 414 connected to a single output aperture 210 (for example, as shown in FIG. 4B).

Referring next to FIGS. 3A-3C, optical coupling between a single concentrator element 202, light guide 204 and output aperture 210 are shown. In particular, FIG. 3A is a cross-sectional diagram of concentrator element 202 and a single output aperture 210 of light guide 204; FIG. 3B is a cross-sectional diagram of concentrator element 202 and two output apertures 210-1, 210-2 of light guide 204; and FIG. 3C is an overhead view diagram of concentrator element 202 and light guide 204 including light guide concentrators 310-1, 310-2.

Referring to FIG. 3A, concentrator element 202 may include primary concentrator element 302 for collecting input light 112 and providing concentrated light 114 to light guide 204. According to an exemplary embodiment, primary concentrator element 302 may be spaced apart from light guide 204, such as by a free space or by an optically transparent layer coupled between primary concentrator element 302 and light guide 204. According to another embodiment, concentrator element 202 may include secondary concentrator element 304, such as a V-trough, a compound parabolic concentrator or a lens, to further concentrate light concentrated by primary concentrator element 302.

Light guide 204 may include input-coupling element 306, output-coupling element 308 and output aperture 210. Input-coupling element 306 may be configured to optically couple (i.e., redirect) concentrated light 114 into light guide 204. Output-coupling element 308 may be configured to optically couple (i.e., extract) guided light 116 out of output aperture 210. Guided light 116 may be directed from output aperture 210 to PV cell 206 which may be directly or remotely coupled to output aperture 210.

Input-coupling element 306 and output-coupling element 308 may include any suitable coupling element, such as, but not limited to, a reflector (for example, a 45° reflective facet as shown in FIG. 3A); reflective and/or refractive microstructures (for example, micro-grooves including prism structures and/or pyramid structures, micro-cones, micro-dots, micro-spheres, micro-cylinders); a reflective and/or refractive surface having a random roughness (such as a diffuser or a textured surface); a surface including a reflective paint; a surface including an optical grating; or by scattering particles on one or more surfaces or in the body of light guide 204. A reflective facet may be formed, for example, by reflective coatings or by total internal reflection. Because input-coupling element 306 and output-coupling element 308 may include structures such as microstructures, scattering particles and/or optical gratings, these structures may create some microscopic differences in the thickness of light guide 204. It is understood, however, that any differences in the thickness due to these structures (of input-coupling element 306 and output-coupling element 308) represent small-scale changes to the thickness relative to the overall uniform thickness of light guide 204, and thus the term “substantially uniform thickness” as used herein includes structures with or without such microstructures. By contrast, however, the term “substantially uniform thickness” as used herein is intended to exclude a stepped waveguide, such as the waveguides disclosed in U.S. Pat. Nos. 7,664,350 and 7,672,549.

Although input-coupling element 306 and output-coupling element 308 are each illustrated, in FIG. 3A, as being reflective facets, input-coupling element 306 and output-coupling element 308 may be configured using different types of coupling components. It is understood that the dimensions and density of light-guide coupling region 309 and the shape of input-coupling elements 306 may be optimized for maximum optical power collection from primary concentrator element 302 (and optionally secondary concentrator element 304) and optimal flux transfer inside of light guide 204.

Although FIG. 3A illustrates light guide 204 having a single output aperture 210, light guide 204 may include two or more output apertures 210. For example, FIG. 3B illustrates light guide 204 including a single input-coupling element 306 and two output-coupling elements 308-1, 308-2 coupled to respective output apertures 210-1, 210-2. Light from output apertures 210-1, 210-2 are directed to respective PV cells 206-1, 206-2. FIG. 3B also illustrates concentrator element 202 including primary concentrator element 302 spaced apart from light guide 204.

Light guide 204 may be directly coupled to one or more output-coupling elements 308. According to another embodiment, as shown in FIG. 3C, light guide 204 may also include one or more light guide concentrators 310. In FIG. 3C, respective light guide concentrators 310-1, 310-2 are provided between light guide 204 and respective output-coupling elements 308-1, 308-2.

Light guide concentrator 310 may include any suitable structure for condensing guided light 116 (FIG. 3A). Light guide concentrator 310 may also include, for example, compound parabolic concentrators (CPCs), curved reflectors, or lenses. Light guide concentrator 310 may be formed to be coplanar with light guide 204. Light guide concentrator 310 may condense the light propagating into, out of, or within light guide 204. Light guide concentrator 310 may be part of a structured waveguide (for example, a tapered waveguide or a CPC shaped waveguide to increase the light intensity, a lensed waveguide surface or a reflective curved facet fabricated from a waveguide that focuses the propagating light) or a standalone element. Another example of light concentrator 310 includes a holograph. Additional concentration may be provided by reducing a thickness of light guide 204. Besides converging (i.e., concentrating) the light, light propagating into, out of, or within light guide 204 may be manipulated in other manners (for example, diverged), with different optical divergence structures (such as a negative lens). Although concentrator 310 is illustrated as being between light guide 204 and respective output-coupling elements 308-1, 308-2, concentrator 310 may be disposed between input-coupling elements 306 and light guide 204 or may disposed outside of light guide 204, to condense the light propagating into or out of light guide 204.

Referring next to FIGS. 4A and 4B, exemplary light collection and conversion systems 400, 410 having multiple light guides 204 (204′) are shown. In particular, FIG. 4A is an overhead view diagram of system 400 where concentrator elements 202 of respective sub-array 406 are optically coupled into a single light guide 204; and FIG. 4B is an overhead view diagram of system 410 where concentrator elements 202 of respective sub-array 406 are optically coupled into separate light guides 204′, which are then combined into single light guide 414.

Referring to FIG. 4A, system 410 includes two-dimensional (2D) array 404 of concentrator elements 202 disposed over light guide layer 106. Light guide layer 106 includes a plurality of light guides 204. The 2D array 404 includes sub-arrays 406 of concentrator elements 202. Each light guide 204 is associated with a respective sub-array 406. Each light guide 204 includes a plurality of input-coupling elements 306. Each input-coupling element 306 is associated with a respective concentrator element 202 of corresponding sub-array 406. Light from each light guide 204 is coupled to respective PV cell 206.

In FIG. 4A, PV cell 206 is illustrated as being formed on circuit board 402 disposed adjacent to light guide layer 106. It is understood that circuit board 402 may be located remote from light guide layer 106. Accordingly, light guides 204 may be remotely optically coupled to PV cells 206, for example, via optical fibers.

Input-coupling elements 306 may be configured so that a single light guide 204 may be used to collect and guide light from multiple concentrator elements 202 of corresponding sub-array 406. Each light guide 204 may be disposed in a coplanar arrangement in light guide layer 106. Concentrator elements 202 may be configured for on-axis imaging, with respective input-coupling element 306 disposed on the corresponding optical axis of concentrator element 202.

Referring next to FIG. 4B, exemplary system 410 is shown. System 410 is similar to system 400 (FIG. 4A) except that system 410 includes separate light guide 204′ for each respective concentrator element 202 of sub-array 406. Separate light guides 204′ may be combined by light guide combiners 412 into single light guide 414, and directed to respective PV cell 206. In FIG. 4B, concentrator element 202 may be configured for off-axis imaging, so that input-coupling element 308 may not be disposed on the optical axis of the respective concentrator element 202. Multiple light guides 204′ and light guide 414 may be arranged in a coplanar manner in light guide layer 106.

According to another embodiment, each light guide 204′ may include a respective turning elements coupled to input-coupling element 306. Accordingly, concentrator elements 202 may be configured for on-axis imaging, with respective input-coupling element 306 disposed on the corresponding optical axis of concentrator element 202.

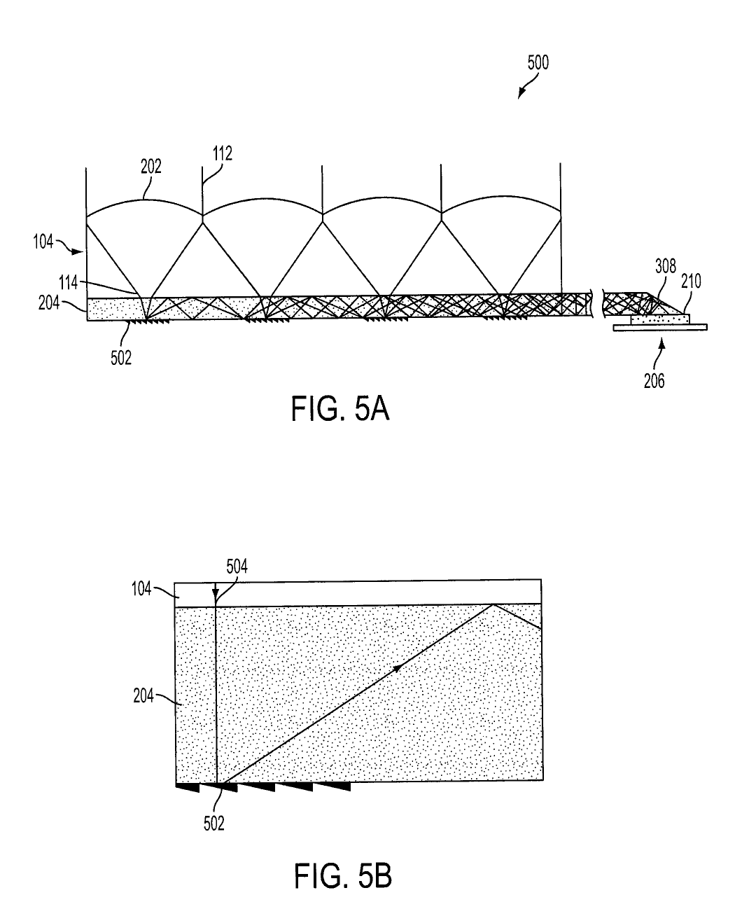

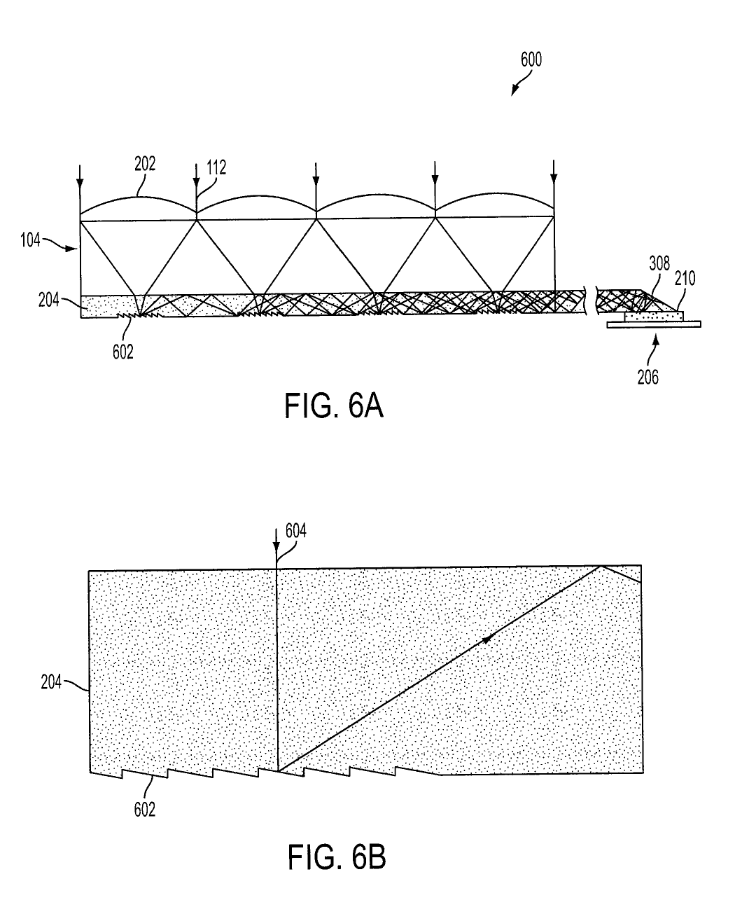

Referring next to FIGS. 5A-6B, exemplary light collection and conversion systems 500 and 600 are shown which include micro-grooves 502 (602) as input-coupling elements. In particular, FIG. 5A is a cross-sectional diagram of system 500 illustrating micro-grooves 502 associated with each concentrator element 202; FIG. 5B shows a portion of light concentrator layer 104 and light guide 204 illustrating light ray 504 redirected by micro-grooves 502; FIG. 6A is a cross-sectional diagram of system 600 including micro-grooves 602 formed directly in light guide 204; and FIG. 6B is a portion of light guide 204 illustrating light ray 604 redirected by micro-grooves 602.

Referring to FIGS. 5A and 5B, system 500 illustrates a plurality of concentrator elements 202 of light concentrator layer 104 optically coupled to light guide 204. The components of system 500 are similar to those shown in FIG. 3A, except that system 500 includes micro-grooves 502 as input-coupling elements. Micro-grooves 502 may include a plurality of protrusions extending from a surface of light guide 204 to couple concentrated light 114 into light guide 204. Micro-grooves may be formed in any suitable geometry to couple concentrated light 114 into light guide 204 using, for example, total internal reflection or reflective coatings. Each concentrator element 202 is associated with respective micro-grooves 502. As shown in FIG. 5B, light ray 504 (from respective concentrator element 202) is directed to micro-grooves 502. Light ray 504 is redirected by micro-grooves 502 into light guide 204.

Referring to FIGS. 6A and 6B, exemplary system 600 is shown. System 600 is similar to system 500, except that system 600 includes micro-grooves 602 formed as apertures in a surface of light guide 204. Each concentrator element 202 is associated with respective micro-grooves 602. As shown in FIG. 6B, light ray 604 from respective concentrator element 202 is redirected by micro-grooves 602 in light guide 204 into light guide 204.

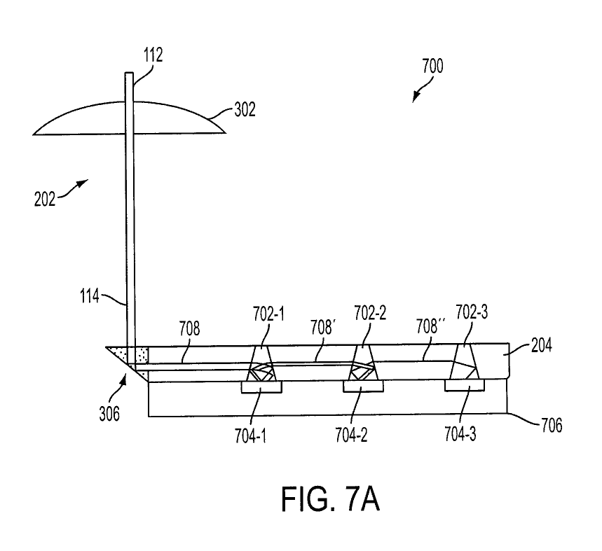

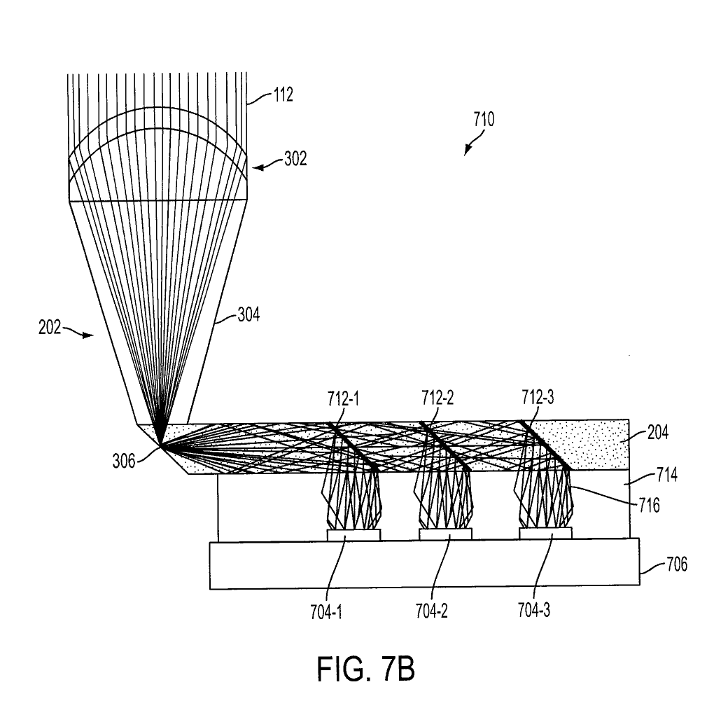

Referring next to FIGS. 7A and 7B, exemplary light collection and conversion systems 700, 710 are shown which are configured to split input light 112 into different wavelengths bands. Each wavelength band may include one or more wavelengths. Accordingly, systems 700 and 710 represent spectrum-splitting photovoltaic systems. In particular, FIG. 7A is a cross-sectional diagram of system 700 including prism structures 702 for separating input light 112 into different wavelength bands; and FIG. 7B is a cross-sectional diagram of system 710 including beam splitters 712 for separating input light 112 into different wavelength bands. In FIGS. 7A and 7B, a single concentrator element 202 is shown, for simplification. It is understood that a plurality of concentrator elements 202 may be associated with each light guide 204, as described above.

System 700 includes concentrator element 202 and at least one light guide 204. Concentrator element 202 may include primary concentrator element 302. As described above, concentrator element 202 may also include a secondary concentrator element 304 (as shown in FIG. 7B). Light guide 204 includes input-coupling element 306 to direct concentrated light 114 (concentrated by concentrator element 202) into light guide 204. Light guide 204 also includes prism coupling structures 702-1, 702-2, 702-3 associated with different wavelength bands (for example, red light, green light and blue light, respectively). PV cells 704-1, 704-2, 704-3 may be optically coupled to outputs of respective structures 702-1, 702-2, 702-3. PV cells 704-1, 704-2, 704-3 may have different energy band-gaps associated with the respective wavelength bands of structures 702-1, 702-2, 702-3, for collecting light in the respective wavelength bands. PV cells 704 may be disposed on circuit board 706 and directly coupled to light guide 204. According to another embodiment, PV cells 704 may be remotely coupled to light guide 204, for example, via optical fibers.

Each PV cell 704 may be coated with respective beam splitting layers that transmit light with one or more wavelengths in a corresponding wavelength band that may be absorbed by the respective PV cell 704 while reflecting the remaining light. When concentrated light 114 enters a respective prism structure 702 with a refractive index higher than a material of light guide 204, the photons may be reflected via total internal reflection and directed to an associated PV cell 704.

For example, light 708 may enter prism structure 702-1. Light 708 directed to the associated PV cell 704-1 having an energy above the respective band-gap energy of PV cell 704-1 may be absorbed and converted into an electrical signal. The remainder of the light may be reflected by the respective beam splitting layer and guided out of prism structure 702-1 (through a respective output facet) and continue to propagate along light guide 204 as light 708′. Thus light 708′ not absorbed by a PV cell 704-1 may continue to propagate through light guide 204 until it is absorbed by another PV cell 704 (for example, by PV cell 704-2). Similarly, light 708″ that is not absorbed by PV cell 704-2 may continue to propagate through light guide 204 until it is absorbed by another PV cell 704, such as PV cell 704-3.

Referring to FIG. 7B, another exemplary system 710 for spectrum-splitting of input light 112 is shown. System 710 is similar to system 700, except that prism structures 702 are replaced by beam splitters 712. Beam splitters 712-1, 712-2, 712-3 are configured to transmit light of respective different wavelength bands and to reflect the remaining light. Thus, in system 710, light of one or more wavelengths in a wavelength band associated with a respective energy band-gap of PV cell 704 may be directed to the appropriate PV cell 704. System 710 also illustrates optical medium 714 between light guide 204 and circuit board 706. Output light 716 from respective beam splitters 712-1, 712-2, 712-3 may be guided through optical medium 714 and provided to respective PV cells 704-1, 704-2, 704-3. Optical medium 714 may include one or more additional concentrators (for example, a CPC or a lens structure) to further adjust the concentration and irradiance pattern on respective PV cells 704-1, 704-2, 704-3.

Referring next to FIGS. 8A and 8B, exemplary light collection and conversion systems 800, 810 are shown which have respective reflective light concentrator layers 104′, 104″. In particular, FIG. 8A is a cross-sectional diagram of system 800 including concave mirror 802 disposed below light guide 204; and FIG. 8B is a cross-sectional diagram of system 810 including curved reflector 812 disposed below light guide 204.

System 800 is similar to system 500 (FIG. 5A) except that reflective light concentrator layer 104′ is disposed below light guide 204, to reflect input light 112 into light guide 204. Light concentrator layer 104′ includes concave mirror 802 spaced apart from light guide 204. In operation, input light 112 may pass through light guide 204 and may be reflected by concave mirror 802. The reflected light from concave mirror 802 may be concentrated by concave mirror 802 and may be coupled into light guide 204 by respective input-coupling elements (illustrated in FIG. 8A as micro-grooves 602). According to another embodiment, light concentrator layer 104′ may include a secondary concentrator elements between concave mirror 802 and light guide 204, as described above.

Referring to FIG. 8B, system 810 having reflective light concentrator layer 104″ is shown. System 810 is similar to system 800 except that system 810 includes curved reflector 812 disposed on light guide 204. In system 800, concave mirror 802 represents a hollow reflector spaced apart from light guide 204 by an air gap. In system 810, curved reflector 812 represents a solid medium and may be easier to integrate with light guide 204 than concave mirror 802.

Referring next to FIG. 9, an exploded perspective view of light collection and conversion system 900 is shown. System 900 includes a one-dimensional (1D) array 902 of concentrator elements 904 and a single light guide 906. Light guide 906 includes micro-grooves 908 which represent input-coupling elements for directing light concentrated by 1D array 902 into light guide 906. Light guide 906 also includes output-coupling element 910 for directing light guided by light guide 906 to PV cell 912. Although PV cell 912 is illustrated as being directly coupled to light guide 906, it is understood that PV cell 912 may be remotely coupled to light guide 906, as described above.

Referring back to FIG. 1, according to an exemplary embodiment, optical sheets 102 may be fabricated using plastic molding techniques. By using plastic molding techniques, optical sheets 102 may be fabricated with low-cost and high precision. Because optical sheets 102 and light conversion apparatus 110 may be spatially decoupled, a lightweight optical sheet 102 having a small form factor may be fabricated and may be mounted on a supporting structure (for example, a portable device, a roof or a tracking device) with PV cells of light conversion apparatus 110 at a different location. PV cells of light conversion apparatus 110 may be directly integrated into a common circuit board together with other micro-chips with conventional fabrication processes. Accordingly, it may not be necessary to include an additional circuit board for the PV cells. The PV cells may be fabricated and integrated onto the circuit board along with other micro-chips according to conventional fabrication processes. Optical sheet 102 may be directly mounted onto a device or circuit board via direct or remote coupling, as described above.

Exemplary optical sheets 102 of the present invention may be integrated into a number of different devices. It is contemplated that exemplary optical sheets 102 may be, for example, integrated into a display screen of a portable device (such as a mobile phone or a portable computer). As another example, optical sheets 102 may be integrated as part of a roof-mounted photovoltaic system. The present invention is illustrated by reference to two examples. The examples are included to more clearly demonstrate the overall nature of the invention. These examples are exemplary, and not restrictive of the invention.

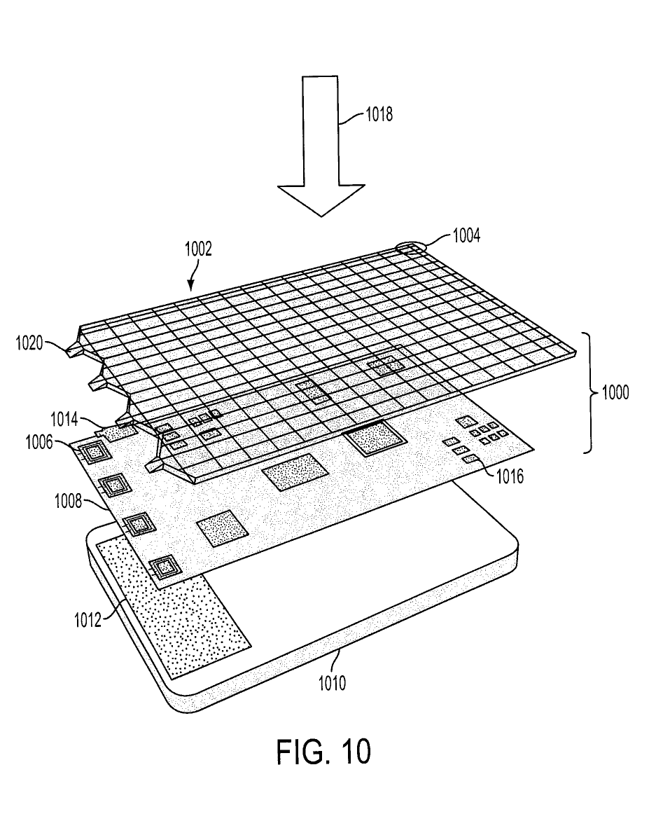

Referring next to FIG. 10, an exemplary light collection and conversion system 1000 coupled to portable device 1010 is shown. System 1000 includes optical sheet 1002 having a plurality of concentrator elements 1004 and a plurality of light guides (not shown) having respective output apertures 1020. System 1000 also includes PV cells 1006 disposed on circuit board 1008. Circuit board 1008 may also include integrated circuits 1016 and battery connector 1014. PV cells 1006 may be used to supply energy to battery 1012 of portable device 1010 via battery connector 1014.

Optical sheet 1002 may be directly disposed on circuit board 1008, such that output apertures 1020 are directly coupled to PV cells 1006. According to another embodiment, optical sheet 1002 may be disposed remote from circuit board 1008, such that output apertures 1020 are remotely coupled to PV cells 1006 (for example, via optical fibers). Accordingly, light 1018 may be collected by optical sheet 1002 and converted to an electrical signal via PV cells 1006, in order to power portable device 1010. Thus, optical power collection (by optical sheet 1002) may be decoupled from energy conversion (by PV cells 1006).

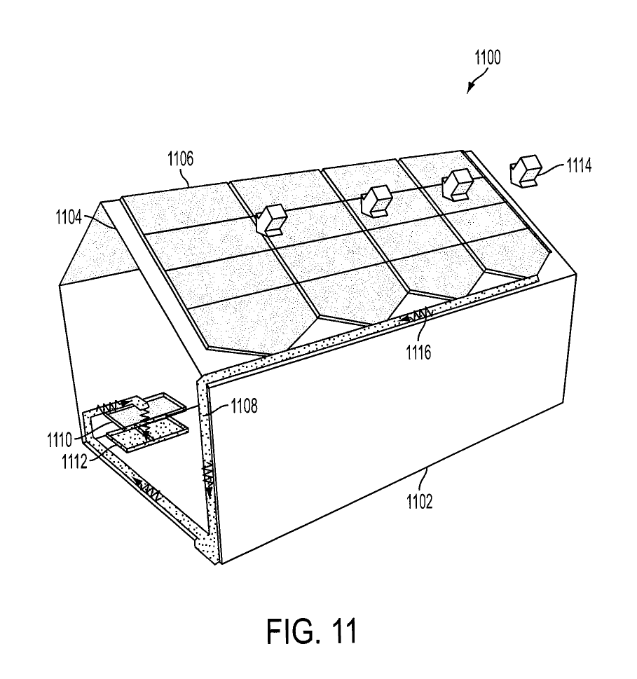

Referring next to FIG. 11, exemplary light collection and conversion system 1100 is shown. System 1100 includes a plurality of optical sheets 1106 mounted to roof 1104 of building 1102. Optical sheets 1106 are configured to collect light 1114 and to transfer photons 1116 to a light conversion component (PV module 1112 and, optionally, secondary optics 1110) via optical cable 1108. Secondary optics 1110 may provide a predetermined concentration or illumination pattern prior to being converted into electrical power by PV module 1112. According to another embodiment, PV module 1112 may be coupled to illumination optics (not shown), for example, to provide indoor illumination. Although not shown, optical sheets 1106 may be coupled to tracking devices, so that optical sheets 1106 may collect an optimum amount of light 1114 throughout the day.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. An optical sheet comprising:
a light guide layer having at least one light guide, each light guide including a plurality of input-coupling elements and at least one output-coupling element, each light guide having a substantially uniform thickness with respect to a propagation direction of light through the light guide; and
a light concentrator layer adjacent to the light guide layer for concentrating incident light, the light concentrator layer including a plurality of concentrator elements optically coupled to the plurality of input-coupling elements of the respective light guide,
wherein each light guide is configured to combine the concentrated light from the respective plurality of concentrator elements and to guide the combined light to the at least one output-coupling element.

2. The optical sheet according to claim 1, wherein each concentrator element includes at least one of an objective lens, a Fresnel lens, a parabolic reflector or a compound-shaped reflector.

3. The optical sheet according to claim 1, wherein each concentrator element includes a primary concentrator element and a secondary concentrator element between the primary concentrator element and the light guide layer.

4. The optical sheet according to claim 3, wherein the secondary concentrator element includes at least one of a V-trough concentrator, a compound parabolic concentrator or a lens.

5. The optical sheet according to claim 1, wherein each input-coupling element includes at least one of a reflector, a plurality of reflective microstructures, a plurality of refractive microstructures, a reflective surface including a random roughness, a refractive surface including the random roughness or an optical grating.

6. The optical sheet according to claim 1, wherein the at least one output-coupling element is configured to pass a portion of the combined light in a wavelength band out of the light guide and to reflect a remaining portion of the combined light to the light guide.

7. The optical sheet according to claim 6, wherein the at least one output-coupling element includes a plurality of output-coupling elements, each output-coupling element configured to pass a different wavelength band.

8. The optical sheet according to claim 1, wherein each light guide includes at least one of a planar waveguide, a rectangular waveguide, an optical plate or an optical fiber.

9. The optical sheet according to claim 1, wherein the at least one light guide includes a plurality of coplanar light guides.

10. The optical sheet according to claim 1, wherein the light concentrator layer is configured to receive the incident light and to refract the incident light to the at least one light guide.

11. The optical sheet according to claim 1, wherein the light concentrator layer is configured to receive the incident light passed through the light guide layer and to reflect the incident light to the at least one light guide.

12. The optical sheet according to claim 1, wherein the light guide layer includes a concentrator structure between the at least one light guide and at least one of:
a) the corresponding plurality of input-coupling elements or b) the at least one output-coupling element.

13. The optical sheet according to claim 12, wherein the concentrator structure includes at least one of a tapered waveguide, a compound parabolic concentrator shaped waveguide, a reflective curved facet, a holograph or a lensed waveguide surface.

14. The optical sheet according to claim 1, wherein the light guide layer includes a divergence structure between the at least one light guide and at least one of: a) the corresponding plurality of input-coupling elements or b) the at least one output-coupling element.

15. A light collection and conversion system comprising:
at least one optical sheet, each optical sheet including:
a light guide layer including at least one light guide, each light guide having a substantially uniform thickness with respect to a propagation direction of light through the light guide, and a light concentrator layer adjacent to the light guide layer for concentrating incident light, a plural number of concentrator elements of the light concentrator layer optically coupled to each light guide; and
a light conversion apparatus optically coupled to the at least one optical sheet via the at least one light guide.

16. The system according to claim 15, wherein the light conversion apparatus is remotely coupled to the at least one optical sheet.

17. The system according to claim 15, wherein the light conversion apparatus is directly coupled to the at least one optical sheet.

18. The system according to claim 15, wherein the at least one light guide includes a plurality of coplanar light guides.

19. The system according to claim 15, wherein each light guide includes at least one output-coupling element, the at least one output-coupling element being configured to pass a portion of the combined light in a wavelength band to the light conversion apparatus and to reflect a remaining portion of the combined light to the light guide.

20. The system according to claim 19, wherein the at least one output-coupling element includes a plurality of output-coupling elements, each output-coupling element configured to pass a different wavelength band.

21. The system according to claim 15, wherein the light conversion apparatus includes at least one photovoltaic (PV) cell, the at least one PV cell is optically coupled to the at least one light guide, and the at least one PV cell is disposed on a circuit board having one or more microchips associated with an electronic device.

22. A method of forming an optical sheet comprising:
forming a light guide layer;
forming at least one light guide in the light guide layer having a substantially uniform thickness with respect to a propagation direction of light through the light guide;
forming a plurality of input-coupling elements and at least one output-coupling element for each light guide;
forming a light concentrator layer including a plurality of concentrator elements configured to be optically aligned with the plurality of input-coupling elements of the respective light guide; and
disposing the light guide layer on the light concentrator layer.

23. The method according to claim 22, wherein the forming of the plurality of input-coupling elements includes forming each input-coupling element as at least one of a reflector, a plurality of reflective microstructures, a plurality of refractive microstructures, a reflective surface including a random roughness, a refractive surface including the random roughness or an optical grating.

24. The method according to claim 22, wherein the forming of the light concentrator layer includes forming each concentrator element as a reflective concentrator element.

25. The method according to claim 22, wherein the forming of the light concentrator layer includes forming each concentrator element as a refractive concentrator element.

26. The method according to claim 22, wherein the forming of the at least one light guide includes forming a plurality of coplanar light guides.
